(19) United States
(12) Patent Application Publication
(10) Pub. No.: US 2026/0123030 A1
(43) Pub. Date: Apr. 30, 2026

(54) P-TYPE NITRIDE-BASED TRANSISTOR

(71) Applicant: TEXAS INSTRUMENTS INCORPORATED, Dallas, TX (US)

(72) Inventors: Zhikai Tang, Sunnyvale, CA (US); Sunglyong Kim, Allen, TX (US)

(21) Appl. No.: 18/933,531

(22) Filed: Oct. 31, 2024

(51) Int. Cl. H01L 27/06; H01L 21/8252; H01L 29/20; H01L 29/66; H01L 29/735; H01L 29/778

(52) U.S. Cl. CPC H10D 84/401; H10D 10/01; H10D 10/60; H10D 30/015; H10D 30/475; H10D 62/8503; H10D 84/01; H10D 84/05

(57) ABSTRACT

A semiconductor device includes a first semiconductor material which, in turn, includes a bipolar junction transistor (BJT); and a second semiconductor material on the first semiconductor material. The second semiconductor material includes a field-effect transistor (FET). The BJT and FET are coupled to one another such that the drain current of the FET is boosted and supplied at the emitter terminal of the BJT.

### BACKGROUND

A high electron mobility transistor (HEMT) may include a heterojunction near which a channel may be formed. The heterojunction may be formed using different semiconductor materials. The channel may be turned on or off by applying an appropriate voltage to a gate structure. Gallium nitride (GaN)-based HEMT devices generally have a high breakdown field, high electron mobility, low resistance, high current, faster-switching speed, high thermal conductivity, and excellent reverse-recovery performance, and thus may be suitable for applications where a low-loss and high-efficiency performance is desired, such as power electronics (e.g., power switches), radio frequency (RF) circuits, and the like.

### SUMMARY

This Summary is provided to introduce examples of disclosed concepts in a simplified form, which are further described below in the Detailed Description including the drawings provided.

According to certain aspects, a semiconductor device may include a first semiconductor material including a bipolar junction transistor (BJT); and a second semiconductor material on the first semiconductor material and including a high electron mobility transistor.

According to certain aspects, a method of manufacturing a semiconductor device includes forming a first semiconductor material having a bipolar junction transistor (BJT); and forming a second semiconductor material having a high electron mobility transistor on the first semiconductor material The foregoing summary outlines rather broadly various features of examples of the present disclosure in order that the following detailed description may be better understood. Additional features and advantages of such examples will be described hereinafter. The described examples may be readily utilized as a basis for modifying or designing other examples that are within the scope of the appended claims.

This summary is neither intended to identify key or essential features of the claimed subject matter, nor is it intended to be used in isolation to determine the scope of the claimed subject matter. The subject matter should be understood by reference to appropriate portions of the entire specification of this disclosure, any or all drawings, and each claim.

The foregoing, together with other features and examples, will be described in more detail below in the following specification, claims, and accompanying drawings. This Summary is provided to introduce examples of disclosed concepts in a simplified form, which are further described below in the Detailed Description including the drawings provided.

### BRIEF DESCRIPTION OF THE DRAWINGS

Illustrative examples are described in detail below with reference to the following figures.

FIG. 1 is a cross-sectional view of a high electron mobility transistor (HEMT), according to some examples.

FIG. 2A is a cross-sectional view of a semiconductor device that includes a p-type enhancement-mode field-effect transistor (FET), and an enhancement-mode HEMT, according to some examples.

FIG. 2B is a cross-sectional view of a semiconductor device that includes a p-type depletion-mode FET, and a depletion-mode HEMT, according to some examples.

FIG. 3 is a circuit schematic of a p-type FET and a HEMT that are configured as a half bridge, according to some examples.

FIG. 4 is a circuit schematic of a p-type FET and a HEMT that are configured as an inverter, according to some examples.

FIG. 5A is a cross-sectional view of a semiconductor device that includes a p-type FET and a bipolar junction transistor (BJT), according to some examples.

FIG. 5B is a circuit schematic of the semiconductor device of FIG. 5A including electrical connections between the p-type FET and the BJT, according to some examples.

FIGS. 6, 7, and 8 are cross-sectional views of the semiconductor device of FIG. 5A including electrical connections between the p-type FET and the BJT, according to some examples.

FIG. 9 is a plan view showing the connections between a p-type FET and a BJT included in a semiconductor device, according to some examples.

FIG. 10A is a cross-sectional view of a semiconductor device that includes a p-type FET, an n-p-n BJT and a multitude of p-n junctions adapted to form Zener diodes, according to some examples.

FIG. 10B is a circuit schematic of the semiconductor device shown in FIG. 10A, according to some examples.

FIG. 10C is a cross-sectional view of a semiconductor device that includes a p-type FET, an n-p-n BJT and a multitude of p-n junctions adapted to form Zener diodes, according to some examples.

FIG. 11A is a cross-sectional view of a semiconductor device that includes a HEMT, and a multitude of Zener diodes, according to some examples.

FIG. 11B is a circuit schematic of the semiconductor device shown in FIG. 11A, according to some examples.

FIG. 11C is a cross-sectional view of a semiconductor device that includes a HEMT, and a multitude of Zener diodes, according to some examples.

FIG. 12 and FIG. 13 are cross-sectional view of a semiconductor device including a vertical stack of a p-type FET and a BJT in various operations of a fabrication process, according to some examples.

FIGS. 14 and 15 illustrates a flowchart of the fabrication process illustrated in FIGS. 12 and 13, according to some examples.

The drawings and accompanying detailed description are provided for understanding of features of various examples and do not limit the scope of the appended claims. The examples illustrated in the drawings and described in the accompanying detailed description may be readily utilized as a basis for modifying or designing other examples that are within the scope of the appended claims. One skilled in the art will readily recognize from the following description that alternative embodiments of the structures and methods illustrated may be employed without departing from the principles, or benefits touted, of this disclosure. Identical reference numerals may be used, where possible, to designate identical elements that are common among drawings. The figures are drawn to clearly illustrate the relevant elements or features and are not necessarily drawn to scale.

### DETAILED DESCRIPTION

Aspects of the present disclosure relate to semiconductor devices. In one example, a semiconductor device includes a p-type field-effect transistor (FET) and a bipolar junction transistor (BJT) positioned below the p-type FET and configured to increase the drain current of the p-type FET. In one example, the BJT is an n-p-n BJT positioned below the p-type FET and included in a first semiconductor material, and the p-type FET is included in a second semiconductor material different from the first material. The BJT and p-type FET are configured such that the drain current of the p-type FET is boosted by and supplied at the emitter terminal of the BJT. The increased current of the p-type FET renders the p-type FET suitable for use in a multitude of applications. For example, the p-type FET may be used with an n-type HEMT to form a half-bridge, an inverter, and the like. The semiconductor device may advantageously include a multitude of p-n junctions configured as one or more Zener diodes to protect the gate(s) of the p-type FETs and HEMT(s) against high voltages and currents. The p-type FET and HEMT may be GaN-based field-effect transistors.

A GaN-based field-effect transistor, such as a GaN-based HEMT, may include a heterojunction formed by a channel layer (e.g., a GaN layer) and a barrier layer (e.g., an aluminum gallium nitride (AlGaN) layer). A high-density two-dimensional electron gas (2DEG) region may be formed at the heterojunction to operate as the transistor channel. For example, the 2DEG layer may have a sheet charge density greater than about 1.0×10¹³ cm⁻², and thus can have a low static on-state resistance. GaN-based HEMTs are suitable for use in high frequency and high power applications due to, for example, their high breakdown field, high electron mobility, low static resistance, and high thermal conductivity. P-type GaN-based HEMTs, however, have relatively low currents thus limiting their potential applications. Embodiments of the present disclosure overcome the above shortcomings of p-type GaN-based HEMTs by integrating, within the semiconductor structure that includes the p-type GaN-based HEMT, a BJT transistor configured to boost the drain current of the HEMT.

Various features are described hereinafter with reference to the figures. An illustrated example may not have all the aspects or advantages shown. An aspect or an advantage described in conjunction with a particular example is not necessarily limited to that example and can be practiced in any other examples even if not so illustrated or if not so explicitly described. Further, methods described herein may be described in a particular order of operations, but other methods according to other examples may be implemented in various other orders (e.g., including different serial or parallel performance of various operations) with more or fewer operations.

Various examples are described herein. Although the specific examples may illustrate various aspects of the above generally described features, examples may incorporate any combination of the above generally described features (which are described in more detail in examples below). Three dimensional x-y-z axes are illustrated in some figures for ease of reference. Some cross-sectional views of various semiconductor devices herein may be general depictions to illustrate various aspects or concepts concerning such semiconductor devices. More specifically, some drain contact structures illustrated in cross-sectional views may not necessarily accurately depict a structure of such drain contact contacts, except to the extent described herein. The illustrations of those drain contact structures are to illustrate various aspects or concepts concerning those drain contact structures.

Various examples are described in the context of an HEMT. Some examples may be implemented in enhancement mode lateral HEMTs that are for high voltage (e.g., about 650 V to about 1,200 V) applications or low to medium voltage (e.g., about 10 V to about 100 V, or about 10 V to about 200 V) applications. In other examples, the semiconductor device may include a bidirectional field effect transistor (FET), a gated Schottky barrier diode (e.g., gate-to-drain shorted structure or gate-to-source shorted structure), or similar devices. Some examples may be implemented with any epitaxial structure, any field plate and/or ohmic contact structure, a planar or three-dimensional structure (e.g., fin structure), and/or various other modifications.

For the sake of illustration, some of the examples disclosed herein may focus on group-III nitride-based devices, such as GaN-based HEMTs. However, this disclosure is not limited to GaN-based HEMTs and can be applied to other devices that include heterostructures formed by other semiconductor materials, such as other group-III nitride or other III-V semiconductor materials, where the heterostructures may induce 2DEG at the heterojunction interface.

In the following description, for the purposes of explanation, specific details are set forth in order to provide a thorough understanding of examples of the disclosure. However, it will be apparent that various examples may be practiced without these specific details. For example, devices, systems, structures, assemblies, integrated circuits, and other components may be shown as components in block diagram form in order not to obscure the examples in unnecessary detail. In other instances, well-known devices, processes, systems, structures, and techniques may be shown without necessary detail in order to avoid obscuring the examples. The figures and description are not intended to be restrictive. The terms and expressions that have been employed in this disclosure are used as terms of description and not of limitation, and there is no intention in the use of such terms and expressions of excluding any equivalents of the features shown and described or portions thereof. The word “example” is used herein to mean “serving as an example, instance, or illustration.” Any embodiment or design described herein as “example” is not necessarily to be construed as preferred or advantageous over other embodiments or designs.

GaN-based HEMTs include heterostructures that may induce two-dimensional electron gas (2DEG) at the interface between two GaN-based materials having different bandgaps. In one example, the heterostructure may be formed by a GaN layer and an AlₓGa₍₁₋ₓ₎N layer, where x is the concentration of aluminum. The GaN layer may have a narrower bandgap than the AlₓGa₍₁₋ₓ₎N layer, which may be referred to as a barrier layer because of its wider bandgap. Due to the bandgap mismatch, large conduction-band offset, and spontaneous and piezoelectric polarization properties of the group-III nitride layers, highly-mobile 2DEG may be generated in the GaN layer near the interface of the heterostructure to form a conductive channel in the GaN layer (which is thus referred to as the channel layer). Compared to silicon-based transistors, GaN-based transistors generally have high breakdown electric field, high electron mobility, low on-state resistance, high current, faster-switching speed, high thermal conductivity, and excellent reverse-recovery performance, and thus may be more suitable for applications where a low-loss and high-efficiency performance may be desired, such as power electronics (e.g., power switches).

A GaN-based transistor may include a gate structure positioned between a source structure and a drain structure. The drain structure may include a metal contact that may be coupled to the channel layer directly or indirectly (e.g., through tunneling) and may form an ohmic contact with the channel layer. The source structure may include a metal contact that may be coupled to the channel layer directly or indirectly and may form an ohmic contact with the channel layer. Depending on the architecture of the gate structure, a GaN-based transistor may be an enhancement mode high electron mobility transistor (e-HEMT) or a depletion mode high electron mobility transistor (d-HEMT). For example, the gate structure of an e-HEMT may include a p-GaN layer formed over the barrier layer, and a gate electrical contact (a metal electrode) formed on the p-GaN layer, which together form a p-GaN gate structure. The p-GaN layer of the gate structure may be doped with, for example, magnesium (Mg), which is an acceptor that can make the GaN layer p-type or p-doped. The p-GaN layer may deplete electrons in the 2DEG channel under the p-GaN gate structure, such that the conductive path between the source and drain may be disabled and thus the e-HEMT may be turned off when no gate drive voltage is applied to the gate electrical contact. When a positive voltage above the gate threshold voltage is applied to the gate electrical contact, the gate structure may attract electrons such that the 2DEG under the gate structure may be replete with electrons, thereby turning on the e-HEMT. In contrast, the gate structure of a d-HEMT may include an insulator layer (e.g., a dielectric layer) over the barrier layer, and a gate electrical contact (e.g., a metal electrode) on the insulator layer. When no voltage signal is applied to the gate electrical contact, the 2DEG under the gate structure may not be depleted such that the conductive path in the channel layer between the drain structure and the source structure may be enabled even without a positive gate voltage. A d-HEMT can be turned off by applying a negative gate voltage to the gate electrical contact to deplete electrons from the 2DEG under the gate structure. In some applications such as switch-mode power applications (e.g., power switches), e-HEMTs, rather than d-HEMTs, may be used in order to, for example, decrease leakage current, reduce power loss, simplify the driving circuit, and/or improve device stability.

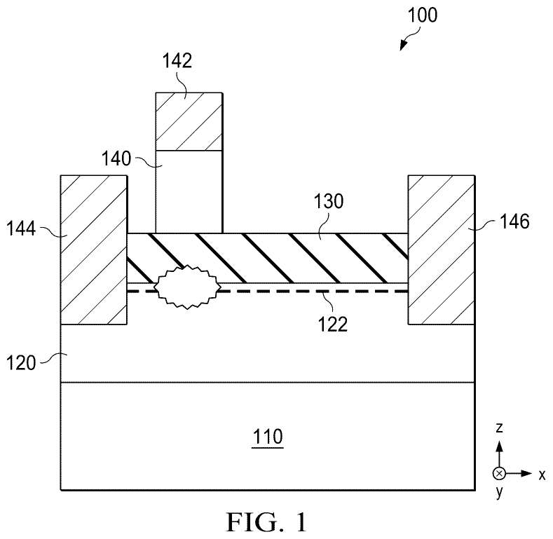

FIG. 1 is a cross-sectional view of an example of a high electron mobility transistor (HEMT) 100. In the illustrated example, HEMT 100 is an e-mode GaN-based transistor that includes a substrate 110, a channel layer 120, a barrier layer 130, a gate structure, a source structure, and a drain structure. Substrate 110 may include, for example, a silicon substrate, a silicon carbide substrate, a semiconductor-on-insulator (SOI) substrate, a sapphire substrate, a gallium nitride (GaN) substrate, a gallium arsenide (GaAs) substrate, an engineered GaN substrate (a Qromis™ Substrate Technology (QST) substrate), a substrate including another semiconductor material that has a bandgap wider than the bandgap of silicon, or any other suitable substrate. In one example, substrate 110 may include a bulk silicon substrate, and may also include one or more transition layers or buffer layers of suitable materials for accommodating the lattice mismatch between substrate 110 and channel layer 120 (e.g., to reduce or minimize lattice defect generation and/or propagation in channel layer 120). For example, the transition layers or buffer layers may have a gradient concentration of one or more elements in a surface normal direction (e.g., z direction) of substrate 110 to gradually change the lattice constant.

Channel layer 120 and barrier layer 130 may be epitaxially grown on substrate 110 to form a heterostructure that may induce a 2DEG 122 layer near the interface between channel layer 120 and barrier layer 130 due to the different energy band structures of channel layer 120 and barrier layer 130. 2DEG 112 may conduct current in a two-dimensional plane (e.g., an x-y plane). In some examples, channel layer 120 may be a portion of substrate 110. Channel layer 120 may include, for example, a GaN layer, an AlGaN layer, or an InAlN layer. In some examples, the material of channel layer 120 may include an unintentionally doped material, such as a material doped by diffusion of dopants from another layer, or includes an intrinsic material. Barrier layer 130 may include, for example, an AlGaN layer. Other materials may also be used for channel layer 120 and barrier layer 130. For example, channel layer 120 may include indium aluminum gallium nitride (InᵢAlⱼGa₁₋ᵢ₋ⱼN) (where 0≤i≤1, 0≤j≤1, and 0≤i+j≤1), and barrier layer 130 may include indium aluminum gallium nitride (InₖAlₗGa₁₋ₖ₋ₗN) (where 0≤k≤1, 0≤l≤1, and 0≤k+l≤1).

The gate structure of HEMT 100 may include a gate semiconductor layer 140 over an upper surface of barrier layer 130. In some examples, gate semiconductor layer 140 may include a p-doped semiconductor layer. For example, gate semiconductor layer 140 may include a GaN layer, or more generally, an InₘAlₙGa₁₋ₘ₋ₙN layer (where 0≤m<1, 0≤n<1, and 0≤m+n≤1). The p-type dopants for doping gate semiconductor layer 140 may include magnesium (Mg), carbon (C), zinc (Zn), and the like, or a combination thereof. In examples where gate semiconductor layer 140 includes GaN doped with a p-type dopant, gate semiconductor layer 140 may be referred to as a p-GaN layer. In some examples, a concentration of the dopant that is electrically activated in gate semiconductor layer 140 may be equal to or greater than about 1×10¹⁷ cm⁻³. In some examples, the concentration may be equal to or greater than about 1×10¹⁸ cm⁻³. Other materials, dopants, and/or concentrations may be used in other examples. Gate semiconductor layer 140 may be formed by epitaxial growth and selective etching using an etch mask, or may be formed by selective area growth using a growth mask. The etch mask or growth mask may define the shape and size of gate semiconductor layer 140. The doping density and the thickness of p-doped gate semiconductor layer 140 and the thickness of barrier layer 130 under gate semiconductor layer 140 may be selected such that the p-doped gate semiconductor layer 140 may deplete 2DEG 122 under gate semiconductor layer 140, such that HEMT 100 is turned off without a positive gate voltage and may be turned on by applying a positive voltage to the gate structure.

A gate electrical contact 142 may be formed on gate semiconductor layer 140 to apply a gate voltage to gate semiconductor layer 140. Gate electrical contact 142 may be electrically coupled to a gate drive circuit though electrical interconnects such as conductive traces and/or vias (now shown). In some examples, gate electrical contact 142 may laterally extend beyond gate semiconductor layer 140 to form a gate field plate, for example, to reduce current collapse and dynamic on-state resistance, and increase the breakdown voltage. Gate electrical contact 142 may include one or more metal and/or metal alloy materials having high electrical conductivity.

At the source region of HEMT 100, a source electrical contact 144 may extend through barrier layer 130 and contact a source region of channel layer 120. Source electrical contact 144 may include a metal or metal alloy and may form a low-barrier metal-to-semiconductor contact (e.g., an ohmic contact) with channel layer 120. In some examples, source electrical contact 144 may not extend through barrier layer 130 and may be electrically coupled to the source region of channel layer 120 through, for example, tunneling effects. In some examples, one or more source field plates may be formed and may be coupled to source electrical contact 144. The source field plates may be used to reduce current collapse and dynamic on-state resistance and/or increase the breakdown voltage of HEMT 100.

At the drain region of HEMT 100, a drain electrical contact 146 may extend through barrier layer 130 and contact a drain region of channel layer 120. Drain electrical contact 146 may include a metal or metal alloy and may form a low-barrier metal-to-semiconductor contact (e.g., an ohmic contact) with channel layer 120. In some examples, drain electrical contact 146 may not extend through barrier layer 130 and may be electrically coupled to the source region of channel layer 120 through, for example, tunneling effects.

Each of gate electrical contact 142, source electrical contact 144, and drain electrical contact 146 may include, for example, titanium (Ti), titanium tungsten (TiW), titanium nitride (TiN), nickel (Ni), platinum (Pt), tantalum nitride (TaN), copper (Cu), tungsten (W), gold (Au), aluminum (Al), an alloy, or a combination thereof. In some examples, the alloy may include, for example, titanium tungsten aluminum (TiWAl) or titanium aluminum nitride (TiAlN), or a combination thereof.

In some examples, HEMT 100 may include one or more dielectric layers (not shown in FIG. 1A) that isolate and protect the gate structure, drain structure, and source structure. The one or more dielectric layers may include a same dielectric material or different dielectric materials deposited in one or more deposition processes. For example, the one or more dielectric layers may include an oxide-based material or a nitride-based material, such as silicon oxide (e.g., a phosphosilicate glass (PSG)), aluminum oxide, silicon nitride, and the like. In some examples, the one or more dielectric layers may further include one or more etch stop layers, such as silicon nitride (SiN) and the like, for controlling the etch depth of etching processes (e.g., for patterning a dielectric or metal layer).

In some examples, the electrical contacts or other metal electrical interconnects in HEMT 100 may each include one or more metal barrier layers and/or one or more adhesion layers (e.g., titanium nitride (TiN), tantalum nitride (TaN), and the like, or a combination thereof) between the metal material (e.g., Al, Cu, W, and the like, or a combination thereof) and the one or more dielectric layers. The one or more metal barrier layers may prevent the diffusion of metal atoms into the one or more dielectric layers. The one or more adhesion layers may be used to improve the adhesion of the metal material to the dielectric material of the one or more dielectric layers to reduce or avoid defects and reliability issues such as interfacial delamination.

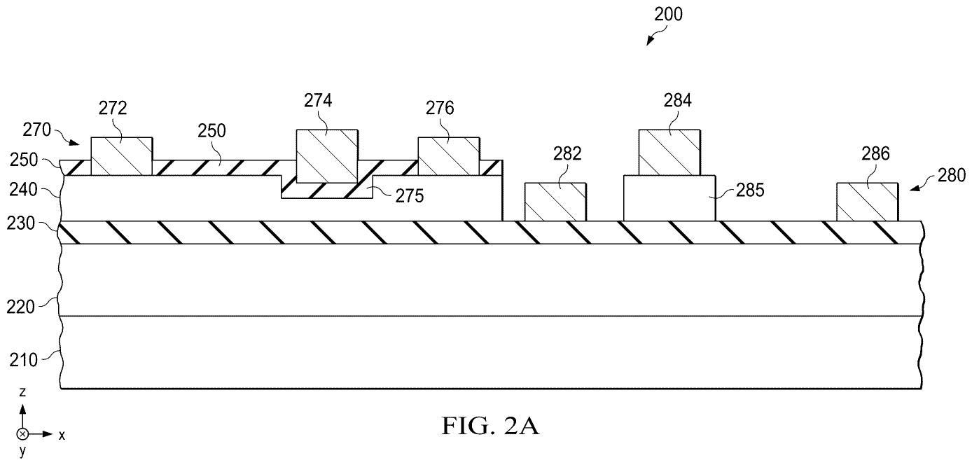

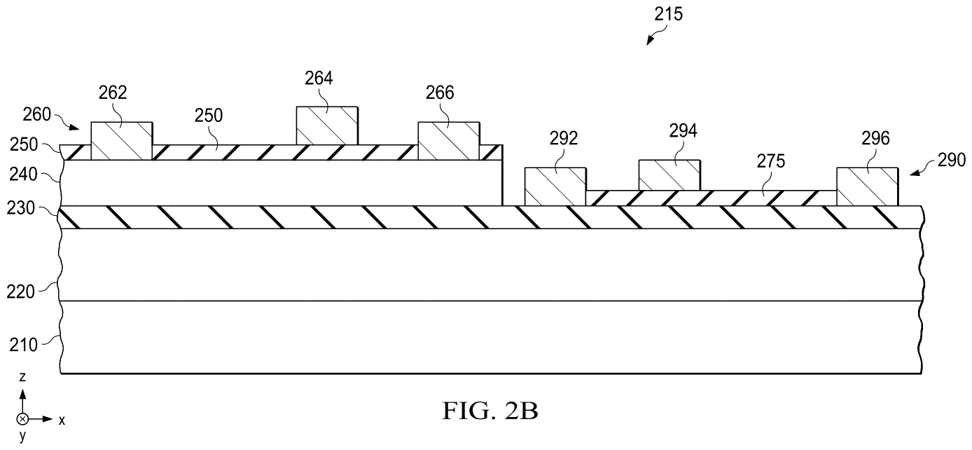

FIG. 2A is a cross-sectional view of a semiconductor device 200 that includes a p-type enhancement-mode field-effect transistor (FET) (alternatively referred to herein as p-type e-mode FET) 270, and an enhancement-mode HEMT (alternatively referred to herein as e-mode HEMT) 280. Semiconductor device 200 is shown as having a vertical stack (e.g., stacked along the z-axis of FIG. 2A) of layers including, in part, a substrate (alternatively referred to herein as semiconductor material) 210, a buffer layer 220 positioned above substrate 210, a barrier layer 230 positioned above buffer layer 220, and a semiconductor layer 240 positioned above barrier layer 230.

P-type e-mode FET 270 is also shown as including, in part, a source structure 272 and a drain structure 276, both of which are formed above semiconductor layer 240. P-type e-mode FET 270 is further shown as including a gate structure 274 positioned partially in recess 275. Recess 275 is formed in semiconductor layer 240 and includes, in part, dielectric layer 250 adapted to insulate gate structure 274 from semiconductor layer 240. The e-mode HEMT 280 is shown as including, in part, a source structure 282 and a drain structure 286, both of which are formed above barrier layer 230. The e-mode HEMT 280 is also shown as including, in part, a gate structure 284 positioned above semiconductor layer 285. Semiconductor layers 240 and 285 may be formed during the same semiconductor manufacturing process but are distinct and not in physical contact with one another.

FIG. 2B is a cross-sectional view of a semiconductor device 215 that includes a p-type depletion-mode FET (alternatively referred to herein as p-type d-mode FET) 260, and a depletion mode HEMT (alternatively referred to herein as d-mode HEMT) 290. Semiconductor device 215 is shown as having a vertical stack of layers including, in part, a substrate 210, a buffer layer 220 positioned above substrate 210, a barrier layer 230 positioned above buffer layer 220, and a semiconductor layer 240 positioned above barrier layer 230. P-type d-mode FET 260 is shown as including, in part, a source structure 262 and a drain structure 266, both of which are formed above semiconductor layer 240. P-type d-mode FET 260 is further shown as including a dielectric layer 250 positioned above semiconductor layer 240, and a gate structure 264 positioned above dielectric layer 250. The d-mode HEMT 290 is shown as including, in part, a source structure 292, and a drain structure 296, both of which are formed above barrier layer 230. The d-mode HEMT 290 is also shown as including, in part, a dielectric layer 275 positioned above barrier layer 230, and a gate structure 294 positioned above dielectric layer 275. In FIG. 2B, the thickness of semiconductor layer 240 below gate structure 264 of p-type d-mode FET 260 is larger than the thickness of semiconductor layer 240 below gate structure 274 of p-type e-mode FET 270. The increased thickness can further separate gate structure 264 from semiconductor layer 240 and reduce the charge depletion in semiconductor layer 240, which allows FET 260 to be a d-mode device with a negative threshold voltage.

Referring to FIGS. 2A and 2Bt, in various examples, substrate 210 may include, a silicon substrate, a silicon carbide substrate, an SOI substrate, a sapphire substrate, a GaN substrate, a GaAs substrate, an engineered GaN substrate (a QST substrate), a substrate including another semiconductor material that has a bandgap wider than the bandgap of silicon, or any other suitable substrate. In some examples, dielectric layers 250 and 275 are formed from the same dielectric material, such as silicon dioxide, and the like. In some examples, buffer layer 220 includes GaN; barrier layer 230 includes AlGaN; and semiconductor layer 240 includes p-type GaN (p-GaN) or other p-type nitride-based semiconductor materials. In some examples, gate structures 274, 284, 264, 294, source structures 272, 282, 262, 292, as well as drain structures 276, 286, 266, and 296 may include titanium (Ti), titanium tungsten (TiW), titanium nitride (TiN), nickel (Ni), platinum (Pt), tantalum nitride (TaN), copper (Cu), tungsten (W), gold (Au), aluminum (Al), an alloy, or any combinations thereof. In some examples, the alloy may include, for example, titanium tungsten aluminum (TiWAl), titanium aluminum nitride (TiAlN), or a combination thereof.

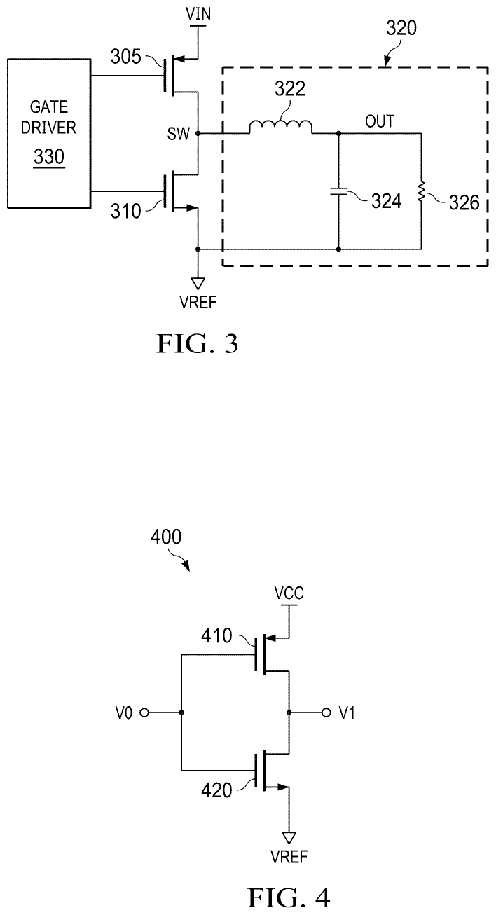

FIG. 3 shows a p-type FET 305 and an n-type HEMT 310 configured as a half bridge to perform voltage conversion (e.g., operate as a buck converter). In FIG. 3, p-type FET 305 is configured as a high side switch, and n-type HEMT 310 is configured as a low side switch. Load 320, which is coupled to the drain terminals of p-type FET 305 and HEMT 310, is shown as including, an inductor 322, a capacitor 324, and a resistor 326. The gate terminals of p-type FET 305 and HEMT 310 are driven by gate driver circuit 330. When gate driver circuit 330 causes p-type FET 305 to turn on and HEMT 310 to turn off, voltage V_{IN} is coupled to a switching terminal (SW in FIG. 3) thereby to charge the SW terminal. Similarly, when gate driver circuit 330 causes HEMT 310 to turn on and p-type FET 305 to turn off, reference voltage V_{ref.}, which may be at the ground potential, is coupled to node A thereby to discharge the SW terminal. By controlling the relative on-time of transistors 305 and 310, the voltage at the output node OUT may be set to a specified value. In one example, p-type FET 305, and HEMT 310 are enhancement mode transistors, such as those shown in FIG. 2A. In another example, p-type FET 305, and HEMT 310 are depletion mode transistors, such as those shown in FIG. 2B. An advantage of using p-type FET 305 as a high side driver is that the voltage at the gate of FET 305 need not exceed VIN (and the SW terminal voltage, which can reach VIN) to turn on the gate of FET 305. In contrast, in a case where FET 305 is an n-type transistor, a bootstrap capacitor and charging circuitry may be needed for the driver circuit of FET 305 to allow the driver circuit to provide a gate voltage higher than VIN to turn on FET 305. Accordingly, using p-type FET 305 as a high side driver can simplify the driver circuit for FET 305.

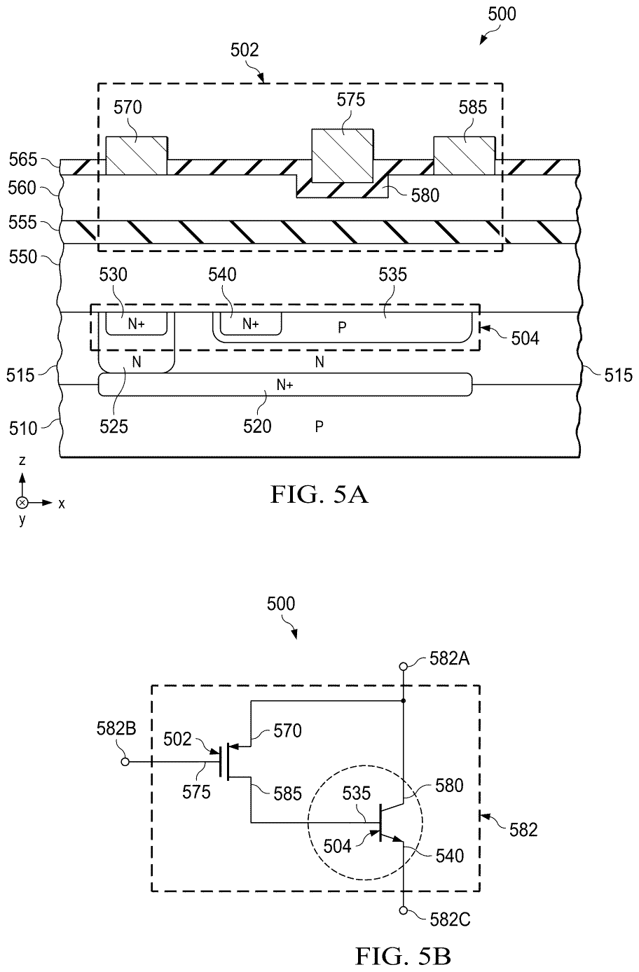

FIG. 4 shows a p-type FET 410 and an n-type HEMT 420 configured as an inverter 400. The source terminals of p-type FET 410 and n-type HEMT 420 are respectively coupled to supply voltage Vcc and the ground potential, and the input voltage V0 and the output voltage V1 can have opposite logic states. Inverter 400 can be an example of digital logic circuits that can be part of control circuitry integrated with other GaN semiconductor devices/systems, such as the half-bridge of FIG. 3, or a high speed GaN device system (e.g., for radio frequency (RF) applications), on a same substrate (e.g., substrate 210), which can reduce interconnects parasitic between the control circuitries and the GaN semiconductor devices/systems, reduce the overall device size, and reduce fabrication complexity and cost.

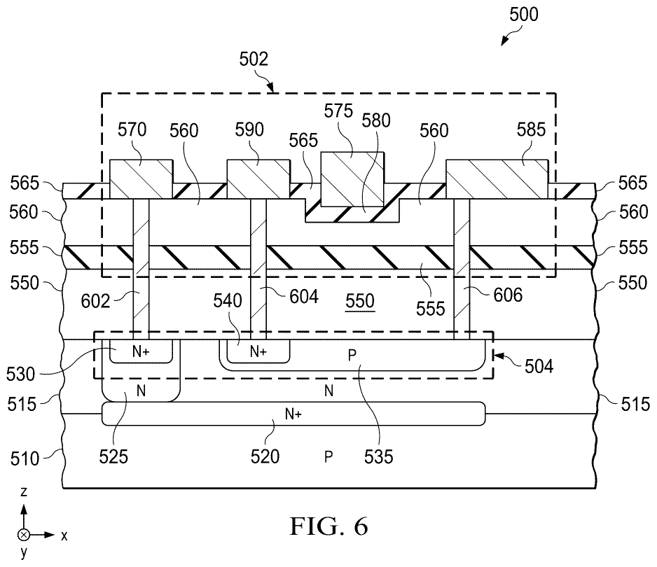

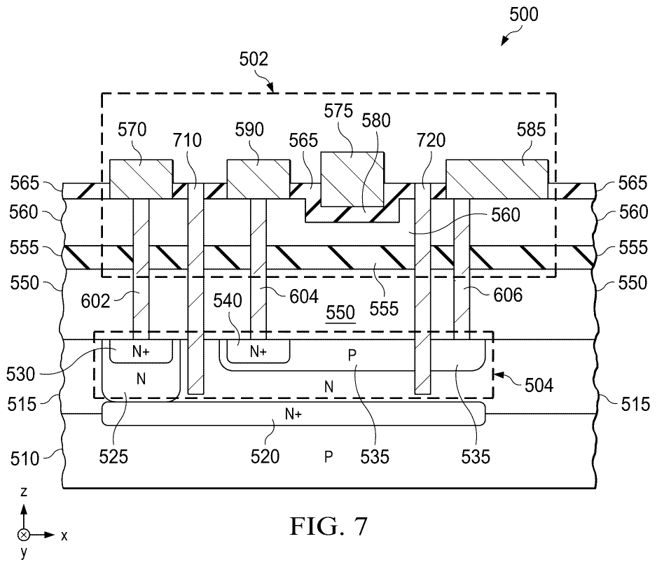

FIG. 5A is a cross-sectional view of a semiconductor device 500, according to some examples. Semiconductor device 500 is shown as including a p-type e-mode FET transistor, and an n-p-n bipolar junction transistor (BJT) configured to boost the drain current of the FET transistor, as described further below.

Semiconductor device 500 is shown as including a vertical stack (e.g., stacked along the z-axis in FIG. 5A) of layers including, in part, a p-type semiconductor material 510, and an n-type semiconductor material 515 formed above p-type semiconductor material 510. In one example, n-type semiconductor material 515 is an epitaxial layer (alternatively referred to herein as n-epi layer) grown over p-type semiconductor material 510. The p-type semiconductor material 510 may be referred to as a semiconductor substrate in some examples. In other examples, p-type semiconductor material 510 and n-epi layer 515 together may be referred to as a semiconductor substrate.

Semiconductor device 500 is also shown as including, in part, an n⁺ buried layer (alternatively referred to herein as region) 520 disposed between p-type semiconductor material 510 and n-epi layer 515, a deep n⁺ sinker layer 525 formed in n-epi layer 515 and extending to buried layer 520, a p-type layer 535 formed in n-epi layer 515, an n⁺ layer 530 formed in deep n⁺ sinker layer 525, and an n⁺layer 540 formed in p layer 535. As is described further below, layers 530, 535 and 540 respectively form the collector, base and emitter regions of a BJT transistor 504.

Semiconductor device 500 is also shown as including, in part, a buffer layer 550 positioned above n-epi layer 515, a barrier layer 555 positioned above buffer layer 550, and a semiconductor layer 560 positioned above barrier layer 555. Semiconductor device 500 is also shown as including, in part, an insulating layer 565 positioned above semiconductor layer 560. Insulating layer 565 also covers the sidewalls and the bottom of recess 580 formed in semiconductor layer 560. Positioned above insulating layer 565 in recess 585 is a gate structure 575 which extends partially above insulating layer 565. Semiconductor device 500 is also shown as including, in part, a source structure 570 and a drain structure 585 positioned above semiconductor layer 560.

Gate structure 575, source structure 570, and drain structure 585 can form, respectively, the gate, source, and drain terminals of a p-type FET 502, which can be an example of p-type e-mode FET 270 of FIG. 2A as shown in FIG. 5A. In some examples, gate structure 575, drain structure 585, and source structure 570 and semiconductor layer 560 can be part of a p-type d-mode FET, such as p-type d-mode FET 270 of FIG. 2B. Accordingly, semiconductor device 500 includes a vertical stack (e.g., stacked along the z-axis of FIG. 5A) of p-type FET 504 and BJT 502.

Electrical connections (i) between the collector of BJT 504 and the source of p-type FET 502; (ii) between the base of BJT 504 and the drain of p-type FET 502, and (iii) to the emitter of BJT 504, as well as to the gate of p-type FET 502 may be made to form various circuitries and to achieve various purposes, as described further below.

In some examples, buffer layer 550 includes a GaN layer, and semiconductor layer 560 includes a p-GaN layer, or other p-type nitride-based semiconductor layer. In some examples, barrier layer 555 includes an AlGaN layer or an indium aluminum gallium nitride layer. As is seen from the example shown in FIG. 5A, the BJT transistor is formed in a first semiconductor material (e.g., substrate 510 and epi layer 515) that is different from the second semiconductor material (e.g., semiconductor layer 560, barrier layer 565 and buffer layer 550) in which the p-type FET is formed. Moreover, the second semiconductor material is on the first semiconductor material. As to be described below, forming the p-type FET 502 on BJT 504 as a vertical stack can reduce the complexity of fabrication.

FIG. 5B is a circuit schematic diagram of electrical connections between p-type FET 502 and BJT 504 of FIG. 5A, according to some examples. As shown in FIG. 5B, FET 502 and BJT 504 can be connected together to form a transistor 582. Transistor 582 has a current terminal 582a coupled to source structure 570 of p-type FET 502 and collector 530 of BJT 504, a gate 582b coupled to gate structure 575 of p-type FET 502, a current terminal 582c coupled to emitter 540 of BJT 504. Drain structure 585 of p-type FET 502 is coupled to base 535 of BJT 504. With such arrangements, the current conducted by transistor 582 from current terminal 582a to current terminal 582b can be controlled by a voltage at gate 582b and boosted by BJT 504, which allows transistor 582 to be used in high power/current density applications, such as a high-side switch of the example half-bridge circuit of FIG. 3, or in high speed applications, such as a logic circuit (e.g., inverter) of FIG. 4.

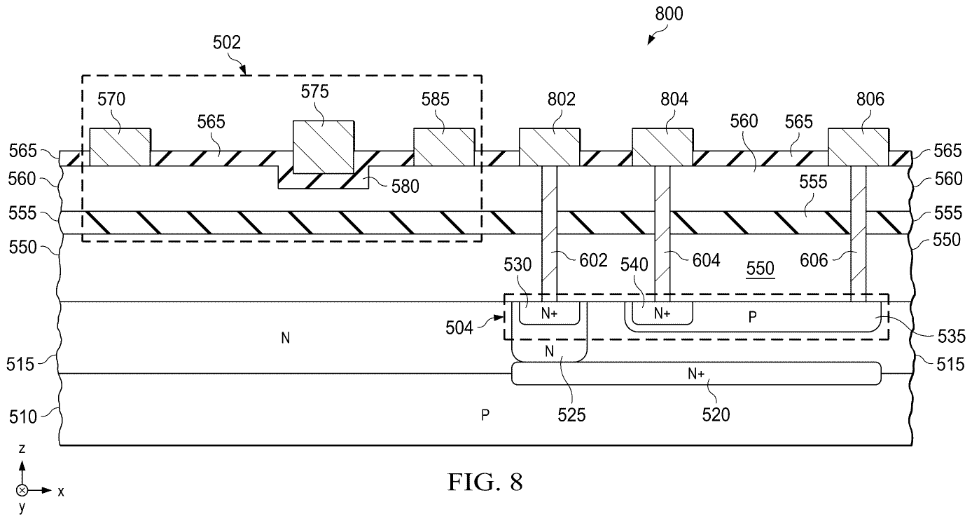

FIG. 6 is a cross-sectional view of semiconductor device 500 showing electrical connections between p-type FET 502 and BJT 504, according to some examples. In the example shown in FIG. 6, the electrical connections are made vertically using through vias 602, 604, and 606 that are filled with one or more conductive materials. Through via 602, which extends vertically through semiconductor layer 560, barrier layer 555, and buffer layer 550, is shown as coupling source structure 570 of p-type FET 502 to the collector 530 of BJT 504. Through via 604, also shown as extending vertically through semiconductor layer 560, barrier layer 555, and buffer layer 550, provides connection to the emitter 540 of the BJT at emitter terminal structure 590 positioned above semiconductor layer 560. Through via 606, which also extends through semiconductor layer 560, barrier layer 555, and buffer layer 550, is shown as coupling drain structure 585 of p-type FET 502 to base 535 of BJT 504. With the arrangements of FIG. 6 where direct electrical connections between the terminals of p-type FET 502 and BJT 504 are made with vertical vias, the metal interconnect as well as the parasitic between p-type FET 502 and BJT 504 can be reduced.

FIG. 7 shows semiconductor device 500 of FIG. 6 that has been further processed to include optional isolation regions 710 and 720 adapted to isolate the drain region of the p-type FET 502 from the source region of the p-type FET 502. Isolation region 710 is an insulator-filled trench that extends from semiconductor layer 560 into epi layer 515, between the deep buried layer 525 and base layer 535. Isolation region 720 is also an insulator-filled trench that extends from semiconductor layer 560 into epi layer 515 through base layer 535. Isolation regions 710 and 720 are shown as terminating above buried layer 520 in this example. The insulating material filling isolation regions 710 and 720 may include any insulating or dielectric materials, such as silicon oxide or silicon nitride. Isolation regions 710 and 720 may be advantageous when, for example, the through vias 602 and 606 associated respectively with the source and drain regions of the p-type FET 502 are positioned in the active area of the p-type FET 502 where the current between the source and drain of the p-type FET 502 may flow. Isolation regions 710 and 720 prevent shorting between source structure 570 and drain structure 580 of p-type FET 502 that would otherwise occur through semiconductor layer 560 (which may be a p-GaN layer) due to the presence of metal in vias 602, 604 and 606.

FIG. 8 is a cross-sectional view of a semiconductor device 800, according to some examples. Semiconductor device 800 is similar to semiconductor device 500 shown in FIG. 6, except that in semiconductor device 800, buried layer 520, deep n⁺ sinker layer 525, and p layer 535 defining, in part, the layers associated with the BJT 504, are positioned laterally away from the p-type FET 502 defined, in part, by gate structure 575, source structure 570 and drain structure 585. Accordingly, the p-type FET 502 and BJT 504 of semiconductor device 800 are not in vertical alignment, the electrical connections between the terminals of the p-type FET 502 and BJT 504, can be formed using lateral metal interconnects (e.g., metal interconnects that extend laterally along the x/y axes) and at higher semiconductor processing layers not shown in FIG. 8. In semiconductor device 800, collector structure/terminal 802 is coupled to collector region 530 of BJT 504 using through via 602, emitter structure/terminal 804 is coupled to emitter region 540 of BJT 504 using through via 604, and base structure/terminal 806 is coupled to base region 535 of BJT 504 using through via 606. Collector structure 802, emitter structure 804, base structure 806, source structure 570, gate structure 575, and drain structure 585, are electrically conductive and provide ohmic contacts. In the example of FIG. 8, because the active region of p-type FET 502 does not overlap with the vias 602, 604, and 606, isolation regions 710 and 720 can be omitted. Because vias 602, 604 and 606 are positioned laterally away from active area of p-type FET 502, the need for isolation regions is dispensed with in semiconductor device 800.

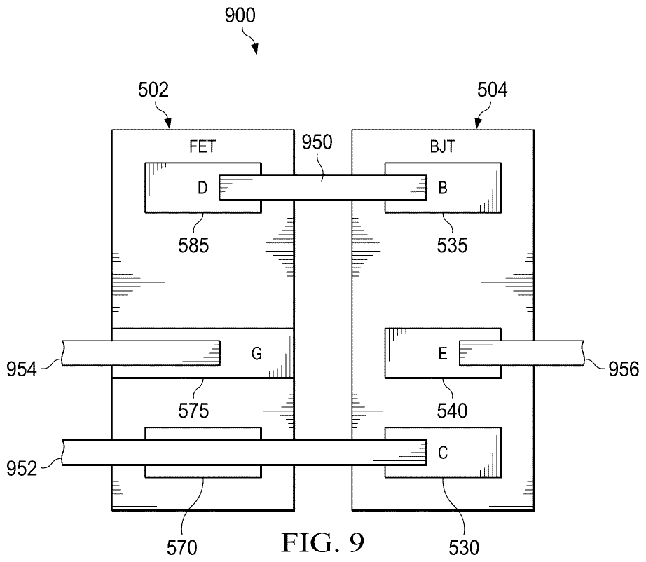

FIG. 9 is a plain view of a semiconductor device 900 including a p-type FET 502 and a BJT 504, according to some examples. Semiconductor device 900 may correspond to semiconductor device 800 of FIG. 8 whose associated p-type FET 502 and BJT 504 are not vertically aligned. Accordingly, in semiconductor device 900, base structure 535, emitter structure 540, and collector structure 530 are coupled to their associated base, emitter and collector regions using their respective through vias, as shown, for example, in FIG. 8.

The p-type FET 502 is shown as including a drain structure 585, a gate structure 575, and a source structure 570. To connect p-type FET 502 to BJT 504 in the manner shown in FIG. 5B, so as to boost the drain current of p-type FET 502, drain structure 585 is coupled to base structure 535 using metal interconnect 950. Collector structure 530 is coupled to source structure 570 using metal interconnect 952. Gate structure 575 is coupled to metal interconnect 954, and emitter structure 540 is coupled to metal interconnect 956. Accordingly, device structure 900 is operated by controlling the relative voltages applied to the device terminals defined by metal interconnects 952, 954 and 956.

In some examples, the base-emitter junction of the BJT of the semiconductor device as described herein, may be configured as a Zener diode to protect the p-type FET or HEMT of the semiconductor device against high voltages and/or high currents. When so configured, the base of the BJT forms the anode of the Zener diode, and the emitter of the BJT forms the cathode of the Zener diode.

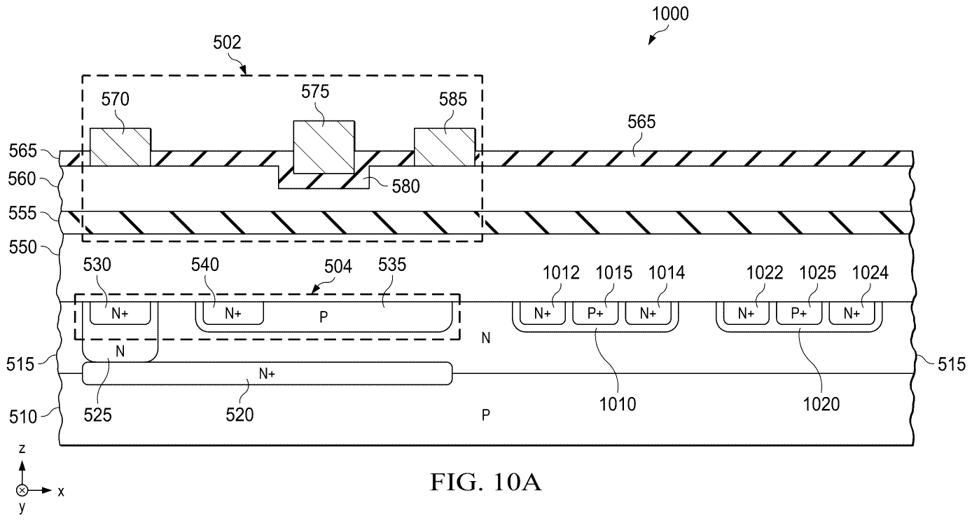

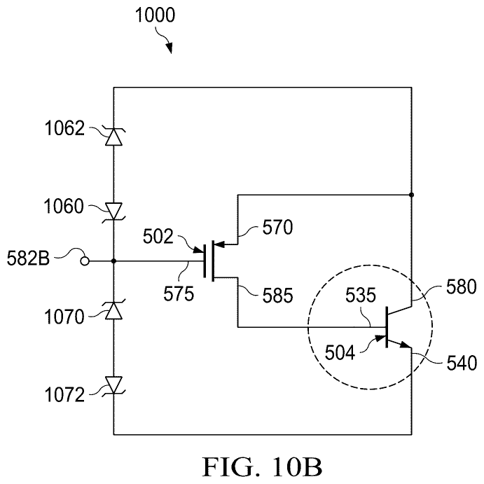

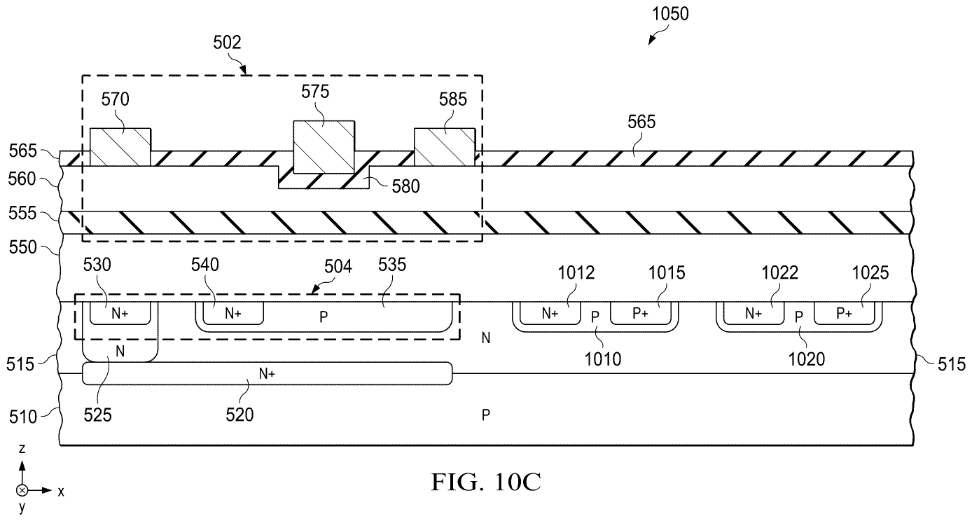

FIG. 10A is a cross-sectional view of a semiconductor device 1000 that includes a p-type FET and an n-p-n BJT. Semiconductor device 1000 is similar to semiconductor device 500 shown in FIG. 5A, except that semiconductor device 1000 includes, in part, additional p-type regions 1010 and 1020 formed in n-type region 515. P-type region 1010 includes n⁺ regions 1012, 1014 adapted to form a first pair of back-to-back Zener diodes, and p-type region 1020 includes n⁺ regions 1022 and 1024 adapted to form a second pair of back-to-back Zener diodes. To protect gate 575 of p-type FET 502 against high voltage and high currents, in some examples, gate structure 575 of p-type FET 502 is coupled to n⁺ regions 1012, and 1022; source structure 570 of p-type FET 502 is coupled to n⁺ region 1014; and the emitter region 540 of BJT 502 is coupled to n⁺ region 1024. P-type region 1010 further includes p⁺ region 1015 used for making contact thereto. Similarly, p-type region 1020 further includes p⁺ region 1025 used for making contact thereto. The connections between the various terminals of the p-type FET 502, BJT 504 and the Zener diodes are not shown in FIG. 10A but may be realized using any number of techniques, such as conductive-filled vias, and/or metal interconnects, as described in detail above.

FIG. 10B is a schematic diagram of semiconductor device 1000 shown in FIG. 10A. Concurrent references are made below to FIGS. 10A and 10B. Zener diode 1060, representative of the diode between n+ region 1012 and p region 1010 of FIG. 10A, has a cathode terminal (n+ region 1012 of FIG. 10A) coupled to the gate terminal of p-type FET 502, and an anode terminal (P region 1010 of FIG. 10A) coupled to the anode terminal of Zener diode 1062. Zener diode 1062, representative of the diode between n+ region 1014 and p region 1010 of FIG. 10A, has a cathode terminal (n+ region 1014 of FIG. 10A) coupled to the source terminal of p-type FET 502. Zener diode 1070, representative of the diode between n+ region 1022 and p region 1020 of FIG. 10A, has a cathode terminal (n+ region 1022 of FIG. 10A) coupled to the gate terminal of p-type FET 502, and an anode terminal (p region 1020 of FIG. 10A) coupled to the anode terminal of Zener diode 1072. Zener diode 1072, representative of the diode between n+ region 1024 and p region 1020 of FIG. 10A, has a cathode terminal (n+ region 1024 of FIG. 10A) coupled to the emitter terminal of BJT 504 of semiconductor device 1000.

FIG. 10C is a cross-sectional view of a semiconductor device 1050 that includes a p-type FET 502 and an n-p-n BJT 504. Semiconductor device 1050 is similar to semiconductor device 1000 shown in FIG. 10A, except that in semiconductor device 1050 p-type region 1010 together with n+ region 1012 form a first Zener diode, and p-type region 1020 together with n+ regions 1022 form a second Zener diode. The two Zener diodes are biased so as to form a back-to-back Zener diodes as shown, for example, between the gate and source regions of p-type FET 502 of FIG. 10B. Contact to p-type region1010 is made using p⁺ region 1015 formed therein, and contact to p-type region is made using p⁺ region 1025 formed therein.

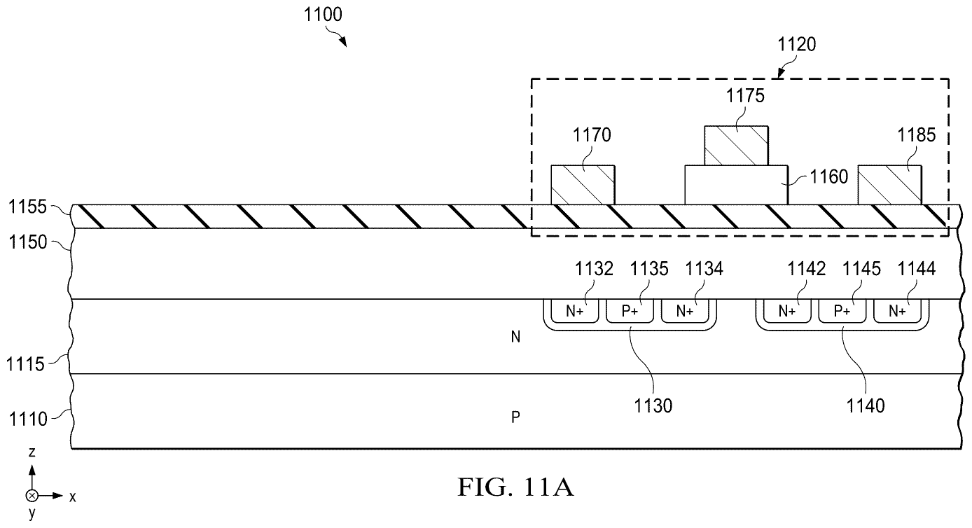

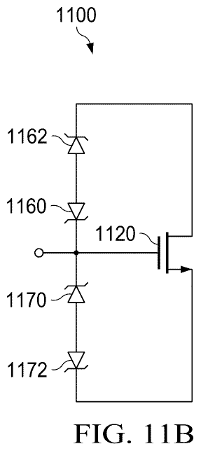

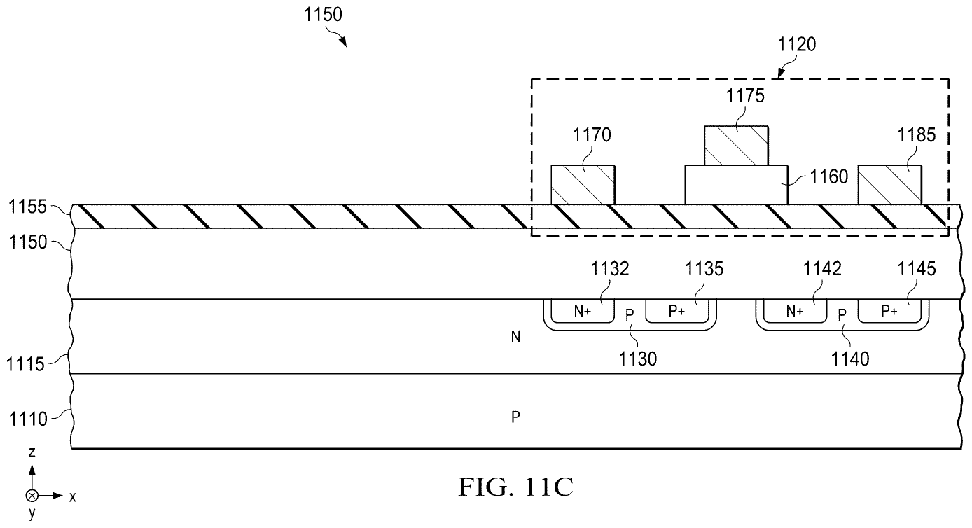

FIG. 11A is a cross-sectional view of a semiconductor device 1100 that includes an e-mode HEMT 1120, and a multitude of Zener diodes, according to some examples. Semiconductor device 1100 is shown as including, in part, a p-type substrate 1110, an epitaxial layer 1115, a buffer layer 1150, and a barrier layer 1155. Semiconductor device 1100 is also shown, as including, in part, a semiconductor layer 1160 formed above which is a gate structure 1175 of HEMT 1120. The source structure 1170, and the drain structure 185 of HEMT 1120 are shown as being formed above barrier layer 1155.

Semiconductor device 1100 is also shown as including, in part, p-type regions 1130 and 1140 formed in n-type region 1115. P-type region 1130 includes n+ regions 1132 and 1134 adapted to form a first pair of back-to-back Zener diodes. P-type region 1140 includes n+regions 1142 and 1144 adapted to form a second pair of back-to-back Zener diodes. To protect gate structure 1175 of HEMT 1120 against high voltage and high currents, in some examples, gate structure 1175 of HEMT 1120 is coupled to n+ regions 1132, 1142, source structure 1170 of HEMT 1120 is coupled to n+ region 1144, and drain structure 1185 of HEMT 1120 is coupled to n+ region 1134. P-type region 1130 further includes p⁺ region 1135 used for making contact thereto. Similarly, p-type region 1140 further includes p⁺ region 1145 used for making contact thereto. The connections between the various terminals of HEMT 1120, and the Zener diodes are not shown in FIG. 11A but may be achieved using any number of techniques, such as conductive-filled vias, and/or metal interconnects, as described in detail above.

FIG. 11B is a schematic diagram of semiconductor device 1100 shown in FIG. 11A. Concurrent references are made below to FIGS. 11A and 11B. Zener diode 1160, representative of the diode between n+ region 1132 and p region 1130 of FIG. 11A, has a cathode terminal (n+ region 1132 of FIG. 11A) coupled to the gate terminal of HEMT 1120 of semiconductor device 1100, and an anode terminal (p region 1130 of FIG. 11A) coupled to the anode terminal of Zener diode 1162. Zener diode 1162, representative of the diode between n+region 1134 and p region 1130 of FIG. 11A, has a cathode terminal (n+ region 1134 of FIG. 11A) coupled to the drain terminal of HEMT 1120. Zener diode 1170, representative of the diode between n+ region 1142 and p region 1140 of FIG. 11A, has a cathode terminal (n+region 1142 of FIG. 11A) coupled to the gate terminal of HEMT 1120, and an anode terminal (p region 1140 of FIG. 11A) coupled to the anode terminal of Zener diode 1172. Zener diode 1172, representative of the diode between n+ region 1144 and p region 1140 of FIG. 11A, has a cathode terminal (n+ region 1144 of FIG. 11A) coupled to the source terminal of HEMT 1120 of semiconductor device 1100.

FIG. 11C is a cross-sectional view of a semiconductor device 1150 that includes an e-mode HEMT 1120, and a multitude of Zener diodes, according to some examples. Semiconductor device 1150 is similar to semiconductor device 1100 shown in FIG. 11A, except that in semiconductor device 1150 p-type region 1130 together with n+ region 1132 form a first Zener diode, and p-type region 1140 together with n+ regions 1142 form a second Zener diode. The two Zener diodes are biased so as to form a back-to-back Zener diodes as shown, for example, between the gate and source regions of HEMT 1120, as shown in FIG. 11B. Contact to p-type region1130 is made using p⁺ region 1135 formed therein, and contact to p-type region 1140 is made using p⁺ region 1145 formed therein.

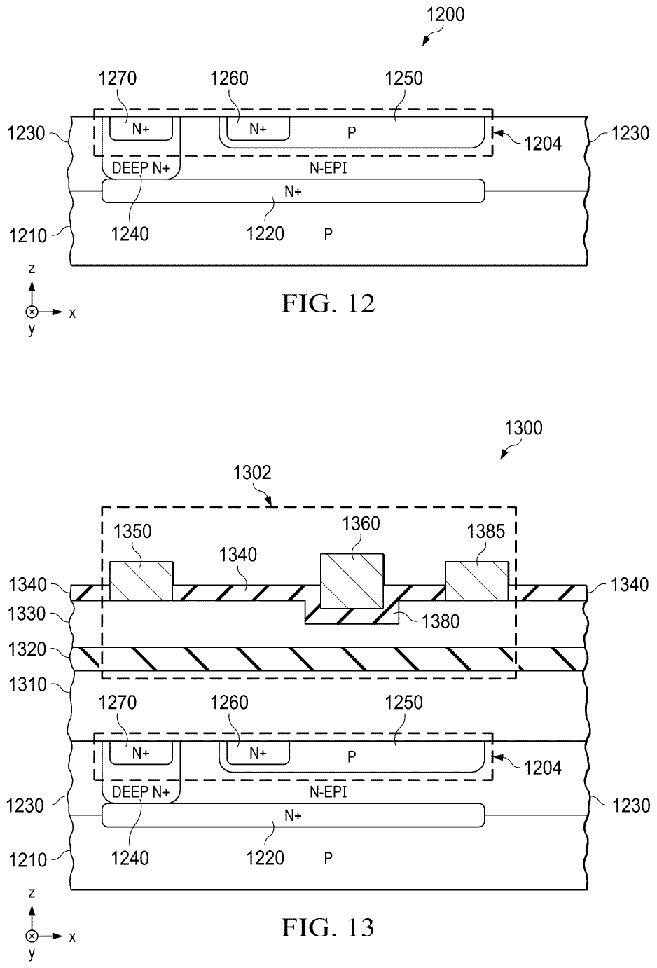

A method of manufacturing a semiconductor device, according to some examples, may include forming a first semiconductor material having a BJT, and forming a second semiconductor material having a FET on the first semiconductor material. FIG. 12 is a cross-sectional view of a semiconductor structure 1200 following a number of processing steps to form an n-p-n BJT. To manufacture semiconductor structure 1200, a p-type semiconductor substrate 1210 with a relatively high resistivity is selected as the first semiconductor material in this example. An n⁺ buried layer 1220 is then formed in the substrate, subsequent to which an n-type epitaxial layer 1230 is grown. Thereafter, a deep n⁺ sinker region 1240 is formed in the epitaxial layer to enable connection to the buried layer. Next, using an ion implantation step, a p-type base layer 1250 is formed in the epitaxial layer. Thereafter, n⁺ layers 1260 and 1270 are formed respectively in base layer 1250 and sinker layer 1240 using another ion implantation step. Layers 1260, 1250 and 1270 respectively represent the emitter, base and collector of BJT 1204 included in semiconductor structure 1200.

FIG. 13 shows a semiconductor structure 1300 formed after further processing of semiconductor structure 1200 of FIG. 12 in order to include a p-type FET 1302 therein, according to some examples. A buffer layer 1310, is grown (e.g., by epitaxial growth) on semiconductor structure 1200. Next, a barrier layer 1320 is grown (e.g., by epitaxial growth) on buffer layer 1310, and a semiconductor layer 1330 is grown (e.g., by epitaxial growth) on barrier layer 1320. In one example, buffer layer 1310 includes GaN, barrier layer 1320 includes AlGaN, and semiconductor layer 1330 includes a p-type GaN (p-GaN) layer epitaxially grown on barrier layer 1320. Source structure 1350 that provides ohmic contact is then formed on semiconductor layer 1330. In FIGS. 12 and 13, buffer layer 1310, barrier layer 1320, and semiconductor layer 1330 can be grown on semiconductor structure 1200, and then patterned to form a p-type FET 1302. Such arrangements can reduce the need for wafer bonding and epitaxial regrowth processes and can reduce the complexity and cost of fabrication.

Recess 1380 is then formed in the semiconductor layer 1330, subsequent to which gate dielectric 1340 is deposited. Next, a layer of gate metal is deposited and patterned to form gate structure 1360. Although not shown in FIG. 13, isolation trenches, as well as conductive-filled through vias may be formed, as shown for example, with reference to FIGS. 6 and 7, to make ohmic contact to the emitter 1260, base 1250 and collector 1270 of BJT 1204. Using metallization (now shown in FIG. 13), collector 1270 of BJT 1204 is coupled to source 1340 of p-type FET 1302, and the base 1250 of BJT 1204 is coupled to drain 1385 of p-type FET 1302 as was described in detail above.

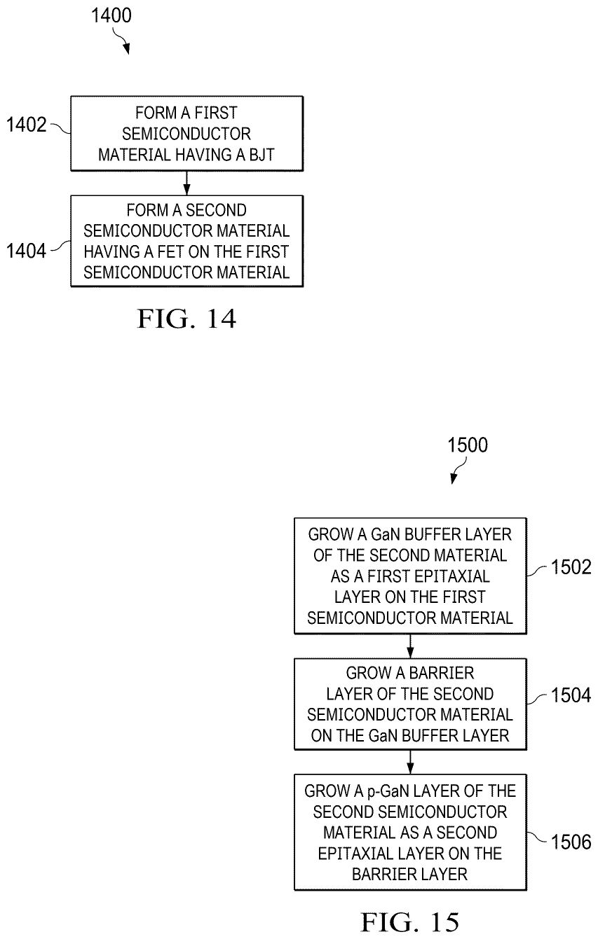

FIG. 14 includes a flowchart 1400 illustrating an example of a process of fabricating examples of a semiconductor device that includes a p-type FET and a BJT as described herein. At 1402, a first semiconductor material having a BJT is formed, such as BJT 1204 shown in FIGS. 12 and 13. At 1404, a second semiconductor material having a FET is formed on the first semiconductor material, such as FET 1302 shown in FIG. 13.

FIG. 15 includes a flowchart 1500 illustrating an example of a process of forming a second semiconductor material on the first semiconductor material, as described in flowchart 1400. At 1502 a GaN buffer layer (such as layer 1310 shown in FIG. 13) of the second semiconductor material is grown as a first epitaxial layer on a substrate (such as layer 1230 of FIG. 13) which can be the first semiconductor material having the BJT in some examples. At 1504, a barrier layer (such as layer 1320 shown in FIG. 13) of the second semiconductor material is grown on the GaN buffer layer. At 1506, a p-GaN layer (such as layer 1330 shown in FIG. 13) of the second semiconductor material is grown as a second epitaxial layer on the barrier layer. The p-GaN layer is then patterned to form a gate structure. In examples where the substrate is not the first semiconductor material, the second semiconductor material can be removed from the substrate and bonded to the first semiconductor material.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on. ” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a field effect transistor (“FET”) (such as an n-channel FET (NFET) or a p-channel FET (PFET)), a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors or other types of device structure transistors. Furthermore, the devices may be implemented in/over a silicon substrate (Si), a silicon carbide substrate (SiC), a gallium nitride substrate (GaN) or a gallium arsenide substrate (GaAs).

References may be made in the claims to a transistor's control input and its current terminals. In the context of a FET, the control input is the gate, and the current terminals are the drain and source. In the context of a BJT, the control input is the base, and the current terminals are the collector and emitter.

References herein to a FET being “on” or “enabled” means that the conduction channel of the FET is present and drain current may flow through the FET. References herein to a FET being “off” or “disabled” means that the conduction channel is not present so drain current does not flow through the FET. An “off” FET, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other examples, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description.

In this description, unless otherwise stated, “about,” “approximately” or “substantially” preceding a parameter means being within +/−10 percent of that parameter or, if the parameter is zero, a reasonable range of values around zero.

Terms “and” and “or,” as used herein, may include a variety of meanings that are also expected to depend at least in part upon the context in which such terms are used. Typically, “or” if used to associate a list, such as A, B, or C, is intended to mean A, B, and C, here used in the inclusive sense, as well as A, B, or C, here used in the exclusive sense. In addition, the term “one or more” as used herein may be used to describe any feature, structure, or characteristic in the singular or may be used to describe some combination of features, structures, or characteristics. However, it should be noted that this is merely an illustrative example and claimed subject matter is not limited to this example. Furthermore, the term “at least one of” if used to associate a list, such as A, B, or C, can be interpreted to mean A, B, C, or a combination of A, B, and/or C, such as AB, AC, BC, AA, ABC, AAB, ACC, AABBCCC, or the like.

Although various examples have been described in detail, it should be understood that various changes, substitutions, and alterations can be made therein without departing from the scope defined by the appended claims. The devices, structures, materials, and processes discussed above are examples. Various examples may omit, substitute, or add various procedures or components as appropriate. Also, features described with respect to certain examples may be combined in various other examples. Different aspects and elements of the examples may be combined in a similar manner. Also, technology evolves and, thus, many of the elements are examples that do not limit the scope of the disclosure to those specific examples.

Specific details are given in the description on order to provide a thorough understanding of the examples. However, examples may be practiced without these specific details. For example, well-known circuits, processes, systems, structures, and techniques may have been shown without unnecessary detail in order to avoid obscuring the examples. This description provides examples only, and is not intended to limit the scope, applicability, or configuration of the invention. Rather, the preceding description of the examples will provide those skilled in the art with an enabling description for implementing various examples. Various changes may be made in the function and arrangement of elements without departing from the spirit and scope of the present disclosure. Modifications are possible in the described examples, and other examples are possible, within the scope of the claims.

What is claimed is:

1. A semiconductor device comprising:
a first semiconductor material comprising a bipolar junction transistor (BJT); and
a second semiconductor material on the first semiconductor material and comprising a field-effect transistor (FET).

2. The semiconductor device of claim 1, wherein a source of the FET is coupled to a collector of the BJT at a first current terminal, a drain of the FET is a coupled to a base of the BJT, and an emitter of the BJT is coupled to a second current terminal.

3. The semiconductor device of claim 2, wherein the source is electrically coupled to the collector and the first current terminal at least partially by a first through via, the drain is electrically coupled to the base at least partially by a second through via, and the emitter is electrically coupled to the second current terminal at least partially by a third through via.

4. The semiconductor device of claim 2, further comprising:
a first metal interconnect above the second semiconductor material and coupling the source, the collector, and the first current terminal;
a second metal interconnect above the second semiconductor material and coupling the drain and the base; and
a third metal interconnect above the second semiconductor material and coupling the emitter and the second current terminal.

5. The semiconductor device of claim 3, further comprising a first isolation region between the third through via and the first through via, and a second isolation region between the third through via and the second through via.

6. The semiconductor device of claim 2, wherein the FET is a p-type FET, and wherein the second semiconductor material further comprises a high electron mobility transistor (HEMT).

7. The semiconductor device of claim 6, wherein the p-type FET and the HEMT are configured as a half bridge according to which the first current terminal is coupled to a power input, the second current terminal is coupled to a drain of the HEMT, the source of the HEMT is coupled to a reference voltage, and gates of the p-type FET and the HEMT are coupled to a gate driver circuit.

8. The semiconductor device of claim 6, wherein the p-type FET and the HEMT are configured as an inverter.

9. The semiconductor device of claim 1, wherein a base and an emitter of the BJT are configured as a Zener diode, and wherein a gate of the FET is coupled to a cathode of the Zener diode.

10. The semiconductor device of claim 1, wherein the first semiconductor material comprises a first N-type region configured as a collector of the BJT, a P-type region configured as a base of the BJT, and a second N-type region in the P-type region and configured as an emitter of the BJT.

11. The semiconductor device of claim 10, wherein the first semiconductor material is an N-type epitaxial layer above a P-type semiconductor substrate.

12. The semiconductor device of claim 1, wherein the first semiconductor material is a semiconductor substrate that includes at least one of silicon or silicon carbide.

13. The semiconductor device of claim 1, wherein the second semiconductor material includes P-type Gallium Nitride (pGaN).

14. The semiconductor device of claim 11, further comprising:
a third semiconductor material between the epitaxial layer and the second semiconductor material and comprising a GaN buffer layer; and
a barrier layer between the second semiconductor material and the third semiconductor material.

15. The semiconductor device of claim 1, wherein the FET is a p-type FET, and wherein a gate of the p-type FET is partially in a recess in the second semiconductor material.

16. A semiconductor device comprising:
a silicon-based semiconductor material comprising a first N-type region, a P-type region, and a second N-type region surrounded by the P-type region;
a first P-type Gallium Nitride (p-GaN) layer above the silicon-based semiconductor material;
a dielectric layer above the first p-GaN layer;
a first terminal on the first p-GaN layer and configured as a source of a p-GaN transistor having a channel region partially in the first p-GaN layer, wherein the first terminal penetrates the dielectric layer;
a second terminal on the first p-GaN layer and configured as a drain of the p-GaN transistor, wherein the second terminal penetrates the dielectric layer; and
a third terminal on the dielectric layer and configured as a gate of the p-GaN transistor, wherein the third terminal is laterally between the first and second terminals.

17. The semiconductor device of claim 16, wherein the first N-type region is configured as a collector of a bipolar junction transistor (BJT), the P-type region is configured as a base of the BJT, and the second N-type region is configured as an emitter of the BJT.

18. The semiconductor device of claim 17, wherein the source is electrically coupled to the collector, and the drain is electrically coupled to the base.

19. The semiconductor device of claim 16 further comprising:
a second p-GaN layer distinct from the first p-GaN layer and above the silicon-based semiconductor material;
a GaN buffer layer below the second p-GaN layer;
a fourth terminal on the second p-GaN layer and configured as a gate of an n-GaN transistor;
a fifth terminal on the GaN buffer layer and configured as a drain of the n-GaN transistor; and
a sixth terminal on the GaN buffer layer and configured as a source of the n-GaN transistor.

20. The semiconductor device of claim 19, wherein the n-GaN and the p-GaN transistors are configured as a half bridge according to which the first terminal is coupled to a power input, the second terminal is coupled to the fifth terminal, the sixth terminal is coupled to a reference voltage, and the third and fourth terminals are coupled to a gate driver circuit.

21. The semiconductor device of claim 19, wherein the n-GaN and p-GaN transistors are configured as an inverter.

22. The semiconductor device of claim 17, wherein the base and emitter of the BJT are configured as a Zener diode, and wherein the gate of the p-GaN is coupled to a cathode of the Zener diode.

23. The semiconductor device of claim 16, wherein the silicon-based semiconductor material is an N-type epitaxial layer above a P-type semiconductor substrate.

24. A method of manufacturing a semiconductor device, the method comprising:
forming a first semiconductor material having a bipolar junction transistor (BJT); and
forming a second semiconductor material having a field-effect transistor (FET) on the first semiconductor material.

25. The method of claim 24, wherein forming a second semiconductor material on the first semiconductor material includes:
growing a GaN buffer layer of the second semiconductor material as a first epitaxial layer on the first semiconductor material having the BJT;
growing a barrier layer of the second semiconductor material on the GaN buffer layer; and
growing a p-GaN layer of the second semiconductor material as a second epitaxial layer on the barrier layer.

26. The method of claim 24, wherein forming a second semiconductor material on the first semiconductor material includes:
growing a GaN buffer layer of the second semiconductor material as a first epitaxial layer on a substrate;
growing a barrier layer of the second semiconductor material on the GaN buffer layer;
growing a pGaN layer of the second semiconductor material as a second epitaxial layer on the barrier layer;
removing the second semiconductor material having the GaN buffer, the barrier layer, and the pGaN layer from the substrate; and
bonding the second semiconductor material having the GaN buffer, the barrier layer, and the pGaN layer onto the first semiconductor material having the BJT.

27. The method of claim 25, further comprising:
patterning the p-GaN layer to form a first p-GaN region and a second p-GaN region and exposing part of the barrier layer;
forming a p-type transistor by forming a first source electrode, a first drain electrode, and a first gate electrode on the first pGaN region; and
forming an n-type transistor by forming a second gate electrode on the second pGaN region and forming a second drain electrode and a second source electrode on the exposed part of the barrier layer and on two sides of the second gate electrode.

28. The method of claim 24 further comprising:
coupling a source of the FET to a collector of the BJT at a first current terminal;
coupling a drain of the FET to a base of the BJT; and
coupling an emitter of the BJT to a second current terminal.
